(19) United States
(12) Patent Application Publication
(10) Pub. No.: US 2024/0306366 A1
(43) Pub. Date: Sep. 12, 2024

(54) SEMICONDUCTOR STRUCTURE AND METHOD FOR PREPARING SAME

(71) Applicant: ICLEAGUE Technology Co., Ltd., Jiaxing (CN)

(72) Inventors: WenYu HUA, Jiaxing (CN); FanDong LIU, Jiaxing (CN); Kuan HU, Jiaxing (CN); Ya WANG, Jiaxing (CN); Xing ZHANG, Jiaxing (CN)

(73) Assignee: ICLEAGUE Technology Co., Ltd., Jiaxing (CN)

(21) Appl. No.: 18/669,518

(22) Filed: May 20, 2024

Related U.S. Application Data
(63) Continuation of application No. PCT/CN2022/113843, filed on Aug. 22, 2022.

(30) Foreign Application Priority Data
Jun. 17, 2022 (CN) 202210683524X

(51) Int. Cl. H10B 12/00

(52) U.S. Cl. CPC H10B 12/30; H10B 12/05

(57) ABSTRACT

A semiconductor structure and a method for preparing the same are provided. The semiconductor structure includes: a substrate having a plurality of active regions that are arrayed. Each of the plurality of active regions includes an active portion and an active extension portion. A word line gate structure is positioned in the substrate. The word line gate structure runs through the plurality of active regions. The word line gate structure includes a word line layer and a word line isolation layer. The active extension portion covers a surface of the active portion and is at least partially positioned on the word line gate structure. A word line isolation extension portion is positioned in the active extension portion, where the word line isolation extension portion is connected to the word line isolation layer and formed on a surface of the word line isolation layer.

### CROSS-REFERENCE TO RELATED APPLICATIONS

This application is a continuation of International Application No. PCT/CN2022/113843, filed on Aug. 22, 2022, which claims priority to Chinese Patent Application No. 202210683524X filed on Jun. 17, 2022, the entire disclosures of which are incorporated herein by reference for all purposes.

### TECHNICAL FIELD

The present disclosure relates to the technical field of semiconductors, and in particular, relates to a semiconductor structure and a method for preparing the same.

### BACKGROUND

In the semiconductor structure with a vertical channel structure in the related art, the vertical channel array transistor (VCAT) architecture has a higher storage density over the traditional buried channel array transistor (BCAT) architecture. A capacitor structure of the VCAT architecture is connected to an active region of a vertical channel device. A word line structure is formed in the active region and is aligned with the active region. A contact area between the active region and the capacitor structure is small. Therefore, a higher requirement is imposed on an overlay accuracy (OVL) between the capacitor structure and the active region. As a result, the process is hard to control and formation is not easy. In addition, a resistance between the capacitor structure and the active region is affected, and consequently a failure is caused.

### SUMMARY

An object of the present disclosure is to provide a semiconductor structure and a method for preparing the same. The area of the active region of the semiconductor structure is increased, such that connection of the semiconductor structure to a capacitor structure and formation of the capacitor structure are facilitated, and hence the process difficulty is lowered, and the failure rate is reduced.

Some embodiments of the present disclosure provide a semiconductor structure. The semiconductor structure includes: a substrate, having a plurality of active regions that are arrayed, where each of the plurality of active regions includes an active portion and an active extension portion; a word line gate structure positioned in the substrate, where the word line gate structure runs through the plurality of active regions, and the word line gate structure includes a word line layer and a word line isolation layer, and where the active extension portion covers a surface of the active portion and is at least partially positioned on the word line gate structure; and a word line isolation extension portion positioned in the active extension portion, where the word line isolation extension portion is connected to the word line isolation layer and formed on a surface of the word line isolation layer.

Some embodiments of the present disclosure further provide a method for preparing a semiconductor structure. The method includes: providing a substrate, the substrate having an active portion and a word line gate structure being formed in the substrate, wherein the word line gate structure includes a word line layer and a word line isolation layer; forming an active extension layer on a surface of the substrate; removing a portion of the active extension layer to form an active extension portion, and forming a first opening exposing the word line isolation layer, wherein the active extension portion covers a surface of the active portion and is at least partially positioned on the word line gate structure, and the active extension portion and the active portion collaboratively form an active region; and forming the word line isolation extension portion in the first opening.

### BRIEF DESCRIPTION OF THE DRAWINGS

A more particular description of the examples of the present disclosure will be rendered by reference to specific examples illustrated in the appended drawings. Given that these drawings depict only some examples and are not therefore considered to be limiting in scope, the examples will be described and explained with additional specificity and details through the use of the accompanying drawings.

FIG. 1 is a sectional view of a semiconductor structure along a vertical direction according to some embodiments of the present disclosure;

FIG. 2 is a sectional view of the semiconductor structure along a horizontal direction according to some embodiments of the present disclosure;

FIG. 3 is a schematic sectional structural view of providing a substrate in a method for preparing a semiconductor structure according to some embodiments of the present disclosure;

FIG. 4 is a schematic sectional structural view of forming an active extension layer on a surface of a substrate in a method for preparing a semiconductor structure according to some embodiments of the present disclosure;

FIG. 5 is a schematic sectional structural view of patterning and etching an active extension layer in a method for preparing a semiconductor structure according to some embodiments of the present disclosure;

FIG. 6 is a schematic sectional structural view of etching a portion of a substrate between adjacent word line gate structures to form an isolation trench in a method for preparing a semiconductor structure according to some embodiments of the present disclosure;

FIG. 7 is a schematic sectional structural view of filling a first opening to form a word line isolation extension portion and filling an isolation trench to form an isolation portion in a method for preparing a semiconductor structure according to some embodiments of the present disclosure;

FIG. 8 is a schematic sectional structural view of etching a portion of a substrate between adjacent word line gate structures to form an isolation trench in a method for preparing a semiconductor structure according to some embodiments of the present disclosure;

FIG. 9 is a schematic sectional structural view of filling an isolation trench to form an isolation portion in a method for preparing a semiconductor structure according to some embodiments of the present disclosure;

FIG. 10 is a schematic sectional structural view of forming an active extension layer on a surface of a substrate in a method for preparing the semiconductor structure according to some embodiments of the present disclosure;

FIG. 11 is a schematic sectional structural view of patterning and laser etching an active extension layer in a method for preparing a semiconductor structure according to some embodiments of the present disclosure; and

FIG. 12 is a schematic sectional structural view of forming a word line isolation extension portion and forming an isolation extension portion in a method for preparing a semiconductor structure according to some embodiments of the present disclosure.

### DETAILED DESCRIPTION

Reference will now be made in detail to specific implementations, examples of which are illustrated in the accompanying drawings. In the following detailed description, numerous non-limiting specific details are set forth in order to assist in understanding the subject matter presented herein. But it will be apparent to one of ordinary skill in the art that various alternatives may be used.

Reference throughout this specification to “one embodiment,” “an embodiment,” “an example,” “some embodiments,” “some examples,” or similar language means that a particular feature, structure, or characteristic described is included in at least one embodiment or example. Features, structures, elements, or characteristics described in connection with one or some embodiments are also applicable to other embodiments, unless expressly specified otherwise.

In the semiconductor structure and the method for preparing the same according to the embodiments of the present disclosure, the active region include the active portion and the active extension portion arranged thereon, and the active extension portion covers the surface of the active region and is at least partially positioned on the surface of the word line gate structure, such that the area of the upper surface of the active region is increased, and other structures are conveniently formed in the active region. This reduces the process difficulty compared to an active region having small size. For example, during subsequent formation of the capacitor structure and the other device structures, formation of the capacitor structure is facilitated, and contact connection between the capacitor structure and the active region is facilitated.

### REFERENCE NUMERALS AND DENOTATIONS THEREOF

100-semiconductor structure;
1-active region; 11-active portion; 12-active extension portion;
2-isolation region; 21-isolation portion; 22-isolation extension portion; 23-isolation trench;
3-word line gate structure; 31-word line layer; 32-gate oxide layer; 33-word line isolation layer; 34-word line isolation extension portion;
4-word line trench;
51-first opening; 52-second opening; and
6-active extension layer.

Hereinafter a semiconductor structure 100 and a method for preparing the same according to the present disclosure are described in detail with reference to accompanying drawings and specific embodiments.

The semiconductor structure 100 according to some embodiments of the present disclosure is described in detail hereinafter with reference to attached drawings.

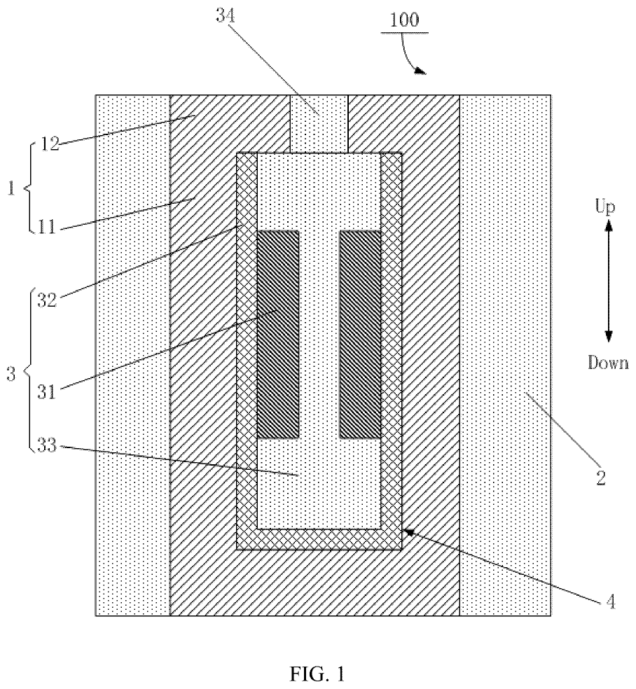

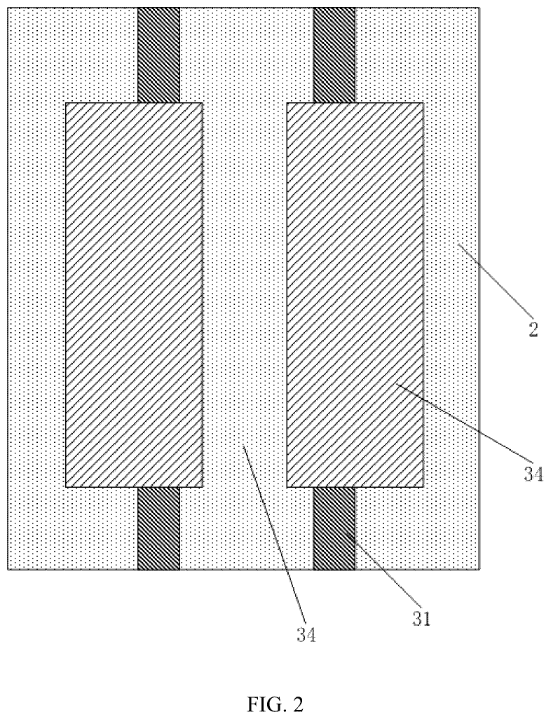

FIG. 1 is a sectional view of a storage unit of a semiconductor structure 100 along a vertical direction according to some embodiments of the present disclosure. FIG. 2 is a sectional view of a storage unit of the semiconductor structure 100 along a horizontal direction according to some embodiments of the present disclosure.

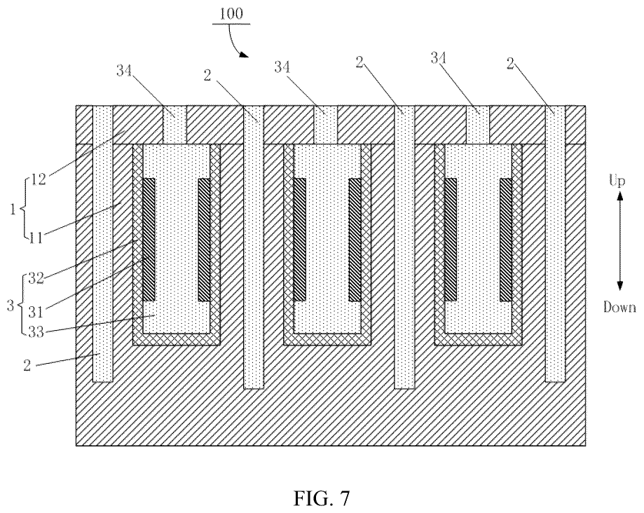

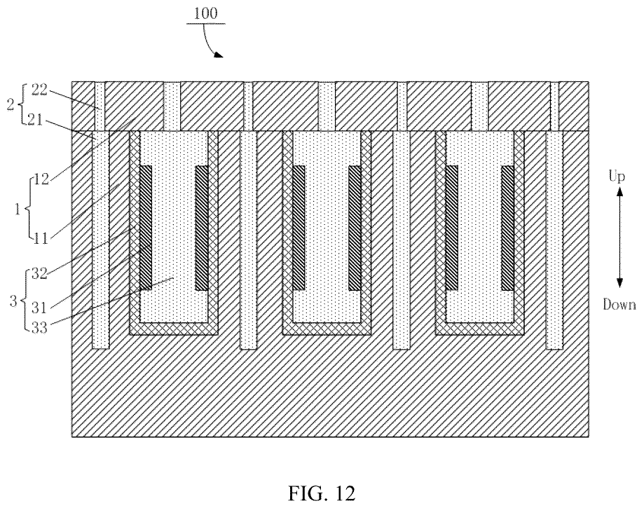

As illustrated in FIG. 1 to FIG. 2, FIG. 7, and FIG. 12, the semiconductor structure 100 according to the embodiments of the present disclosure may include a substrate, a word line gate structure 3, and a word line isolation extension portion 34.

As illustrated in FIG. 7 and FIG. 12, the substrate has a plurality of active regions 1 that are arrayed. The active regions 1 form a columnar structure, and the active regions may be in, but not limited to, a misaligned arrangement to improve an arrangement density of the active regions 1. A plurality of word line gate structures 3 may be arranged. Each of the word line gate structures 3 runs through the active regions 1 along the same direction.

As illustrated in FIG. 1, the word line gate structure 3 is formed in the substrate and runs through a plurality of active regions 1. That is, the word line gate structure 3 is intersected with the plurality of active regions 1 and formed in the active regions 1. The word line gate structure 3 may include a word line layer 31 and a word line isolation layer 33, and the word line isolation layer 33 is formed in the word line layer 31.

As illustrated in FIG. 1, the active region 1 may include an active portion 11 and an active extension portion 12. The active portion 11 and the active extension portion 12 jointly constitute the active region 1. The word line gate structure 3 is formed in the active portion 11, the active extension portion 12 is formed on a surface of the active portion 11, and the active extension portion 12 is at least partially positioned on the word line gate structure 3. That is, the active extension portion 12 is connected to the active portion 11, and the active extension portion 12 covers an upper surface of the active portion 11 and covers a portion of a surface of the word line gate structure 3. In this way, the area of an upper surface of the active extension portion 12 is greater than the area of the upper surface of the active portion 11, and the upper surface of the active extension portion 12 is the upper surface of the active region 1, such that the area of an upper surface of the active region 1 is increased.

The active region 1 of the semiconductor structure 100 according to the embodiments of the present disclosure may be connected to a capacitor structure or other devices. Description is given in the embodiments of the present disclosure hereinafter using connection contact between the active region 1 and the capacitor structure as an example. With reference to FIG. 1 and FIG. 2, the active portion 11 is formed as a columnar structure, the word line gate structure 3 is formed in the active portion 11, and the active extension portion 12 is formed over the active portion 11 and the word line gate structure 3. Where a capacitor structure is formed on the semiconductor structure 100, the capacitor structure may be connected to the active extension portion 12 of the active region 1, the active extension portion 12 is at least positioned on the surfaces of the active region 11 and the word line gate structure 3, such that the upper surface of the active region 1 is increased, and hence the area of a connection surface between the capacitor structure and the active region 1 is increased. During formation of the capacitor structure on the surface in the subsequent process, compared to the semiconductor structure with the active region 1 having a small surface, it is simpler to form the capacitor structure on a larger surface of the active region 1, for example, it is simpler to carry out deposition, etching or the like without the need of a higher overlay accuracy, such that the process difficulty is lowered, and better connection between the active region 1 and the capacitor structure is ensured. In this way, a connection effect between the active region 1 and the capacitor structure is improved, and hence a resistance between a capacitive contact portion and the active region 1 is avoided, and the semiconductor structure 100 is prevented from failure.

The word line isolation extension portion 34 is positioned on the active extension portion 12, the word line isolation extension portion 34 is connected to the word line isolation layer 33 and is formed on a surface of the word line isolation layer 33. The word line isolation layer 33 and the word line isolation extension portion 34 may jointly constitute an isolation structure of the word line 31. By the word line isolation extension portion 34, the active extension portions 12 on the top are isolated, such that subsequent formation of other device structures on the active extension portion 12 is facilitated.

In the semiconductor structure 100 according to the embodiments of the present disclosure, the active region 1 may include the active region 11 and the active extension portion 12. The active extension portion covers the surface of the active portion 11 and is at least partially positioned on the word line gate structure 3, such that the area of the upper surface of the active extension portion 11 is greater than the area of the upper surface of the active portion 11. In this way, by forming the active extension portion 12 on the surface of the active portion 11, the area of the upper surface of the active region 1 is increased, and hence the area of the connection surface between the active region 1 and the capacitor structure is increased. In addition, by increasing the area of the active region 1, formation of the capacitor structure on the surface of the active region 1 in the subsequent process is facilitated, and proper connection between the capacitor structure and the active region 1 is achieved without the need of a higher overlay accuracy, such that the process difficulty is lowered.

In some embodiments, the semiconductor structure further includes: an isolation region, wherein the isolation region is formed between the plurality of active regions.

In some embodiments, the isolation region includes an isolation portion and an isolation extension portion, wherein the isolation extension portion is connected to the isolation portion and positioned on a surface of the isolation portion, the isolation portion is positioned between the active portions, the isolation extension portion is positioned between the active extension portions, and the active extension portions is at least partially positioned on the surface of the isolation portion.

In some embodiments, the semiconductor structure further includes: a capacitive contact portion, wherein the capacitive contact portion is formed on the active extension portion and is connected to the active extension portion.

In some embodiments, a word line trench is formed in the substrate, the word line gate structure is formed in the word line trench, and the word line gate structure further includes a gate oxide layer, wherein the gate oxide layer is formed on a side wall and a bottom wall of the word line trench.

In some embodiments, the word line layer is formed on a side wall of the gate oxide layer, and the word line isolation layer is formed on a bottom wall of the gate oxide layer and a the side wall of the gate oxide layer and a side wall of the word line layer.

In some embodiments, the active extension portion is positioned on a surface of the gate oxide layer and a portion of the surface of the word line isolation layer.

In some embodiments of the present disclosure, with reference to FIG. 7 and FIG. 12, the semiconductor structure 100 further includes an isolation region 2. The isolation region 2 is formed in the substrate and is positioned between the active regions 1. The isolation region 2 surrounds the active regions 1 to isolate the active regions 1. In the embodiments as illustrated in FIG. 1 and FIG. 7, side walls of the isolation regions 2 are aligned, and sides, facing towards the isolation regions, of the active extension portions 12 is aligned with the active portions 11.

In some other embodiments of the present disclosure, as illustrated in FIG. 2, the isolation region 2 may include an isolation portion 21 and an isolation extension portion 22. The isolation extension portion 22 is connected to the isolation portion 21 and is formed on a surface of the isolation portion 21, and the isolation extension portion 22 covers a portion of the surface of the isolation portion 21, wherein the isolation portion 21 is positioned between the active regions 11 to isolate the active regions 11, and the isolation extension portion 22 is positioned between the active extension portions 12 to isolate the active extension portions 12. As illustrated in FIG. 12, the active extension portion 12 is at least partially positioned on the surface of the isolation portion 21, that is, the active extension portion 12 runs towards the isolation region 2 and covers a portion of an upper surface of the isolation portion 21, such that the area of the upper surface the active region is further increased, the difficulty of the process for subsequently forming the capacitor structure is further lowered, and contact connection between the active region 1 and the capacitor structure is facilitated.

In some embodiments of the present disclosure, the semiconductor structure 100 may further includes a capacitive contact portion. The capacitive contact portion is formed on the surface of the active region 1. Specifically, the capacitive contact portion may be formed on the surface of the active extension portion 12. The active region 1 is connected to the active extension portion 12 and the area of the upper surface of the active region 1 is increased, such that formation of the capacitive contact portion on the active region 1 is facilitated, the process difficulty is lowered, the area of the capacitive contact portion is relatively increased, and hence a connection effect between the active region 1 and the capacitor structure is improved and subsequent formation of the capacitor structure is facilitated.

In some embodiments of the present disclosure, a word line trench 4 is formed in the substrate. The word line gate structure 3 is formed in the word line trench 4. The word line gate structure 3 further includes a gate oxide layer 32. The gate oxide layer 32 is formed on a side wall and a bottom wall of the word line trench 4. The gate oxide layer 32 may be formed by thermal oxidation of the side wall and the bottom wall of the word line trench 4, or the gate oxide layer 32 may be formed by directly depositing an oxide on the bottom wall and the side wall of the word line trench 4, which is not limited in the embodiments of the present disclosure.

As illustrated in FIG. 1, the word line layer 31 is formed on the side wall of the gate oxide layer 32, and the word line isolation layer 33 is formed on a bottom wall of the gate oxide layer 32, and a side wall of the gate oxide layer 32 and a side wall of the word line layer 31. That is, the word line isolation layer 33 is formed between the word line layer 31 and the gate oxide layer 32, and fills the word line trench 4, and the word line isolation layer 33 covers the exposed bottom wall and side wall of the gate oxide layer 32 and covers a surface of the word line layer 31.

In some embodiments of the present disclosure, as illustrated in FIG. 1 and FIG. 2, the active extension portion 12 is positioned on a surface of the gate oxide layer 32 and a portion of a surface of the word line isolation layer 33. Further, a side wall of the active extension portion 12 may be aligned with a side, facing towards the word line isolation layer 33 of the word line layer 31, or the side wall of the active extension portion 12 may exceeds the side, facing towards the word line isolation layer 33, of the word line layer 31, such that a width of the active extension portion 12 is further increased, and hence the area of the upper surface of the active extension portion 12 is further increased.

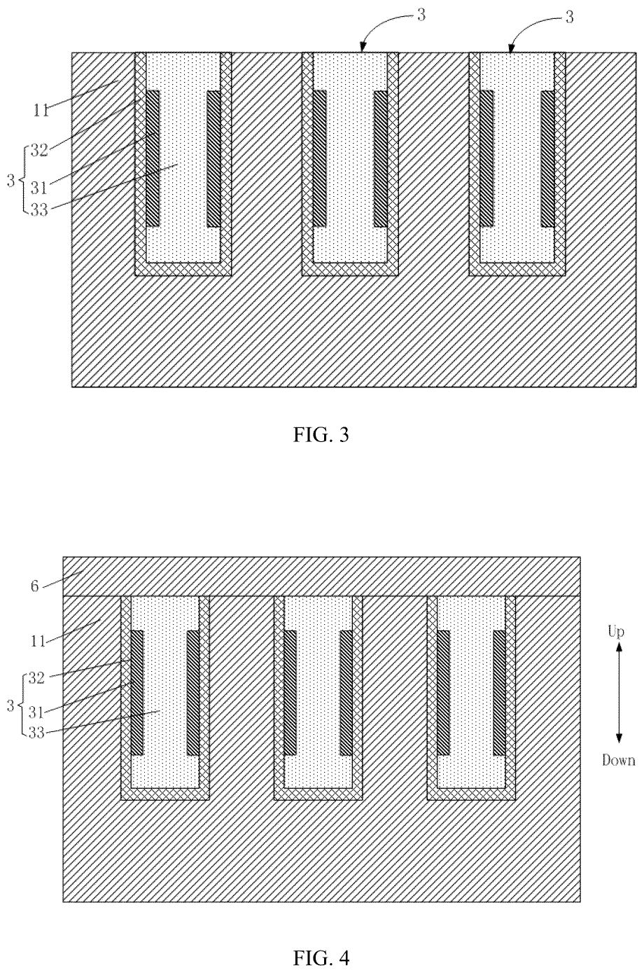

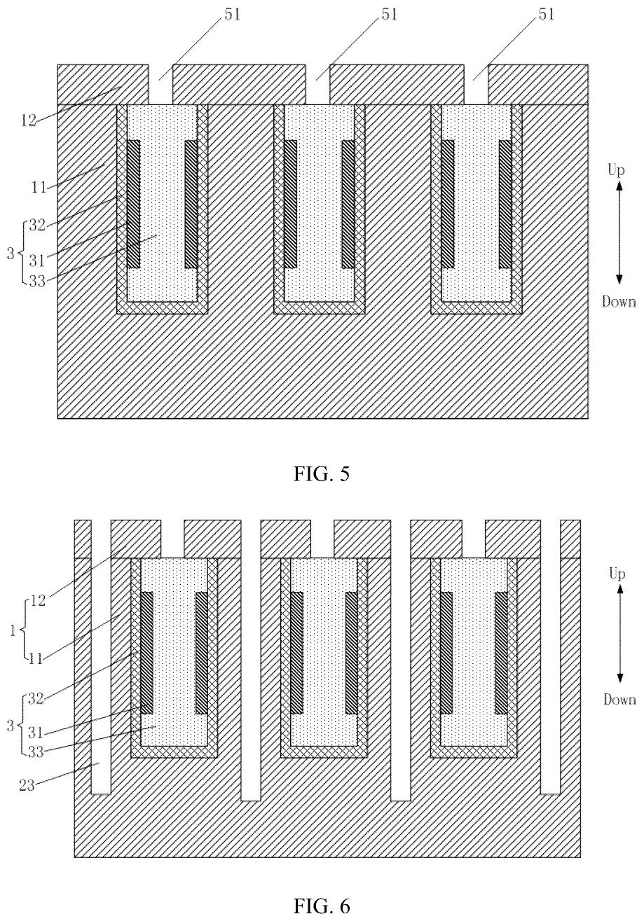

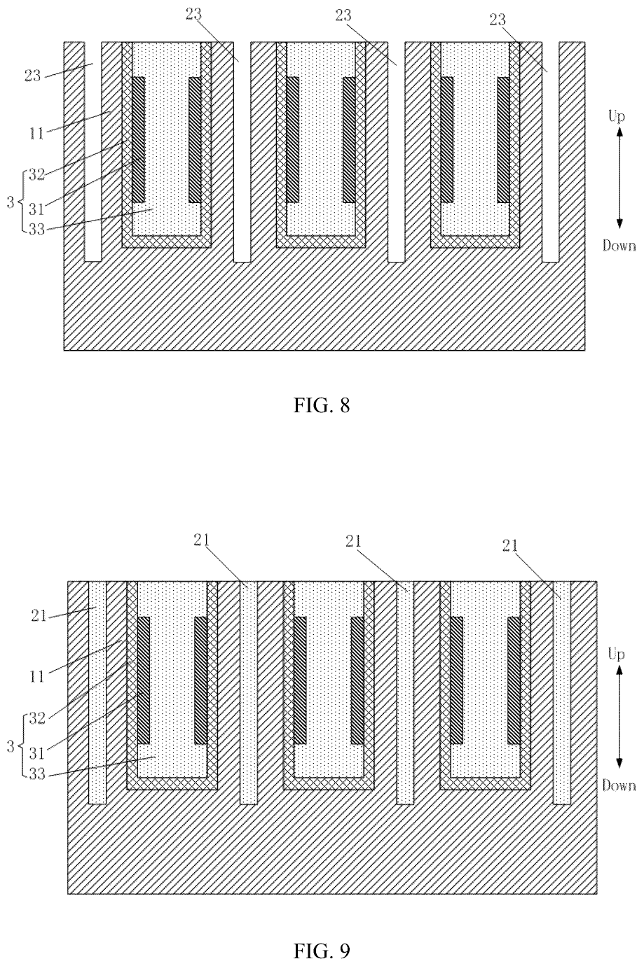

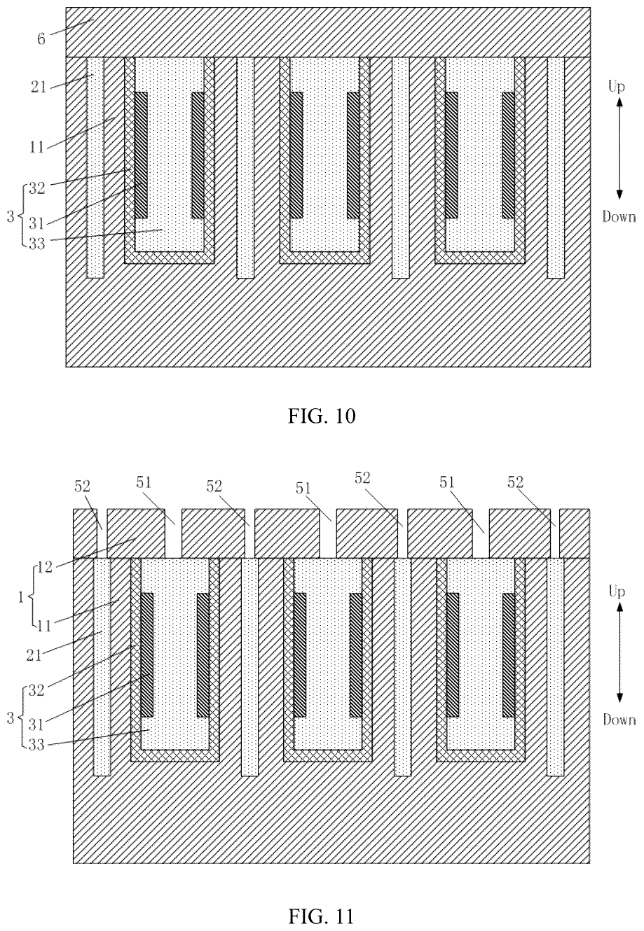

FIG. 3 is a schematic sectional structural view of providing a substrate in a method for preparing a semiconductor structure 100 according to some embodiments of the present disclosure. FIG. 4 is a schematic sectional structural view of forming an active extension layer on a surface of a substrate in a method for preparing a semiconductor structure 100 according to some embodiments of the present disclosure. FIG. 5 is a schematic sectional structural view of patterning and etching an active extension layer 6 in a method for preparing a semiconductor structure 100 according to some embodiments of the present disclosure. FIG. 6 is a schematic sectional structural view of etching a portion of a substrate between adjacent word line gate structures 3 to form an isolation trench 23 in a method for preparing a semiconductor structure 100 according to some embodiments of the present disclosure. FIG. 7 is a schematic sectional structural view of filling a first opening 51 to form a word line isolation extension portion 34 and filling an isolation trench 23 to form an isolation portion 21 in a method for preparing a semiconductor structure 100 according to some embodiments of the present disclosure. FIG. 8 is a schematic sectional structural view of etching a portion of a substrate between adjacent word line gate structures 3 to form an isolation trench 23 in a method for preparing a semiconductor structure 100 according to some embodiments of the present disclosure. FIG. 9 is a schematic sectional structural view of filling an isolation trench 23 to form an isolation portion 21 in a method for preparing a semiconductor structure 100 according to some embodiments of the present disclosure. FIG. 10 is a schematic sectional structural view of forming an active extension layer 6 on a surface of a substrate in a method for preparing a semiconductor structure 100 according to some embodiments of the present disclosure. FIG. 11 is a schematic sectional structural view of patterning and laser etching an active extension layer 6 in a method for preparing a semiconductor structure 100 according to some embodiments of the present disclosure. FIG. 12 is a schematic sectional structural view of forming a word line isolation extension portion 34 and forming an isolation extension portion 22 in a method for preparing a semiconductor structure 100 according to some embodiments of the present disclosure.

A method for preparing a semiconductor structure 100 according to some embodiments of the present disclosure is described in detail hereinafter with reference to attached drawings.

As illustrated in FIG. 1 to FIG. 12, the method includes: providing a substrate, the substrate having an active portion 11 and a word line gate structure 3 being formed in the substrate, wherein the word line gate structure 3 includes a word line layer 31 and a word line isolation layer 33; forming an active extension layer 6 on a surface of the substrate; removing a portion of the active extension layer 6 to form an active extension portion 12, and forming a first opening 51 exposing the word line isolation layer 33, wherein the active extension portion 12 covers a surface of the active portion 11 and is at least partially positioned on the word line gate structure 3, and the active extension portion 12 and the active portion 11 jointly constitute an active region 1; and forming a word line isolation extension portion 34, wherein the word line extension portion 34 fills the first the first opening 51.

As illustrated in FIG. 3, a word line trench 4 is formed in the substrate, the word line gate structure 3 is formed in the word line trench 4, a portion of the substrate surrounding the word line gate structure 3 may be formed into the active portion 11, a plurality of word line gate structures 3 may be arranged, and the plurality of word line gate structures 3 are spaced apart from each other.

As illustrated in FIG. 4 and FIG. 10, the active extension layer 6 is formed on the surface of the substrate, the active extension layer 6 covers the entire surface of the substrate, and the active extension layer 6 may be made of the same material as the active portion 11. Alternatively or additionally, the active extension layer 6 may be a polycrystalline layer.

With reference to FIG. 5 and FIG. 6, and FIG. 11 and FIG. 12, the active extension layer 6 is patterned and etched to remove a portion of the active extension layer 6 to form the active extension portion 12. The active extension portion 12 covers the surface of the active portion 11 and is at least partially positioned on the word line gate structure 3. In this way, the active extension portion 12 simultaneously covers an upper surface of the active portion 11 and an upper surface of a portion of the word line gate structure 3, such that the area of an upper surface of the active extension portion 12 is definitely greater than the area of the upper surface of the active portion 11, and the active portion 11 and the active extension portion 12 may jointly constitute the active region 1. The upper surface of the active extension portion 12 is the upper surface of the active region 1, such that the area of the upper surface of the active region 1 is increased, subsequent formation of the capacitor structure is facilitated, the process difficulty is lowered, the contact area between the active region 1, and the capacitor structure is increased. In this way, impacts to a resistance between the capacitor structure and the active region 1 are avoided.

A first opening 51 exposing the word line isolation layer 33 is formed in the active extension layer 6, and the word line isolation extension portion 34 is formed by filling the first opening 51. The word line isolation extension portion 34 is formed on a surface of the word line isolation layer 33 and is formed between the active extension portions 12.

In some embodiments, an isolation portion is further formed in the substrate, wherein the isolation portion is formed between the active portions; removing the portion of the active extension layer to form the active extension includes forming a second opening exposing the isolation portion in the active extension layer, where the active extension portion is at least partially positioned on a surface of the isolation portion; and forming the word line isolation extension portion includes forming an isolation extension portion in the second opening, where the isolation extension portion and the isolation portion collaboratively form an isolation region.

In some embodiments, removing the portion of the active extension layer to form the active extension portion includes: removing a portion of the active extension portion to form the first opening exposing the word line isolation layer; etching the substrate to form an isolation trench between adjacent active regions; and forming the word line isolation extension portion includes: forming an isolation region in the isolation trench.

In some embodiments, the method for preparing the semiconductor structure further includes: forming a capacitive contact portion, where the capacitive contact portion is formed on the active extension portion and is connected to the active extension portion.

In some embodiments, the method for preparing the semiconductor structure further includes: forming a word line trench in the substrate, where the word line gate structure is formed in the word line trench, the word line gate structure further comprises a gate oxide layer, and the gate oxide layer is formed on a side wall and a bottom wall of the word line trench.

In some embodiments of the method for preparing the semiconductor structure, the word line layer is formed on a side wall of the gate oxide layer, and the word line isolation layer is formed on a bottom wall of the gate oxide layer, the side wall of the gate oxide layer, and a side wall of the word line layer.

In some embodiments of the method for preparing the semiconductor structure, the active extension portion is positioned on a surface of the gate oxide layer and a portion of the surface of the word line isolation layer.

In some embodiments, an isolation portion 21 is further formed in the substrate, wherein the isolation portion 21 is formed between the active portions 11; in removing the portion of the active extension layer 6 to form the active extension portion 12, a second opening 52 exposing the isolation portion 21 is formed in the active extension layer 6, and the active extension portion 12 is at least partially positioned on a surface of the isolation portion 21; and in forming the word line isolation extension portion 34, an isolation extension portion 22 is formed in the second opening 52, wherein the isolation extension portion 22 and the isolation portion 21 jointly constitute an isolation region 2.

Specifically, with reference to FIG. 3 and FIG. 8, the portion of the substrate between adjacent word line gate structures 3 is etched to form an isolation trench 23, and the active portion 11 may be defined by the isolation trench 23. The isolation trench 23 is formed between the active portions 11. As illustrated in FIG. 9, the isolation trench 23 is filled to form the isolation portion 21, and the isolation portion 21 surrounds the active portion 11.

As illustrated in FIG. 10, an active extension layer 6 is formed on the surface of the substrate, wherein the active extension layer 6 covers the surfaces of the active portion 11, the word line gate structure 3, and the isolation portion 21.

As illustrated in FIG. 11, the active extension layer 6 is patterned and laser etched to remove a portion of the active extension layer 6, and the second opening 52 exposing the isolation portion 21 and the first opening 51 exposing the word line isolation portion 33 are defined in the active extension layer 6 to form the active extension portion 12. The active extension portion 12 covers the surface of the active portion 11 and is partially positioned on the surfaces of the isolation portion 21 and the word line gate structure 3. In the example as illustrated in FIG. 11, the active extension portion 12 may be formed into a T-shaped structure, such that the area of the upper surface of the active extension portion 12 is further increased.

As illustrated in FIG. 12, the word line isolation extension portion 34 is formed in the first opening 51, and the isolation extension portion 22 is formed in the second opening 52. The isolation extension portion 22 and the isolation portion 21 jointly constitute the isolation region 2. The active region 1 is formed in each of the active portion 11 and the active extension portion 12, and the isolation region 2 is positioned between the active regions 1 to isolate the active regions 1.

In some embodiments of the present disclosure, removing the portion of the active extension layer 6 to form the active extension portion 12 includes: removing a portion of the active extension portion 12 to form the first opening 51 exposing the word line isolation layer 33; etching the substrate to form an isolation trench between adjacent active regions 1; and in forming the word line isolation extension portion 34, forming an isolation region 2 in the isolation trench.

Specifically, with reference to FIG. 3 and FIG. 4, the active extension layer 6 is deposited on the surface of the substrate, the active extension layer 6 covers the upper surfaces of the active portion 11 and the word line gate structure 3, and the active extension layer 6 may be a polycrystalline layer, wherein the active portion 11 is constituted by the portion of the substrate surrounding the word line gate structure 3.

As illustrated in FIG. 5, the active extension layer 6 is patterned and etched to form the first opening 51 exposing the word line isolation layer 33. As illustrated in FIG. 6, the portion of the substrate between the word line gate structures 3 is etched to form the isolation trench 23 and define the active portion 11, and the isolation trench 23 runs through the active extension layer 6 and extends downward into the substrate.

As illustrated in FIG. 7, the word line isolation extension portion 34 is formed in the first opening 51, and the isolation region 2 is formed in the isolation trench 23, wherein the word line isolation extension portion 34 and the isolation region 2 are formed in the same step, that is, the isolation region 2 may be deposited in the isolation trench 23 while depositing the word line isolation extension portion 34. The isolation region 2 may be made of the same material as the word line isolation extension portion 34, such that the process steps are simplified.

Described above are exemplary embodiments of the present disclosure. It should be noted that persons of ordinary skill in the art may derive other improvements or polishments without departing from the principles of the present disclosure. Such improvements and polishments shall be deemed as falling within the protection scope of the present disclosure.

1. A semiconductor structure, comprising:
a substrate, having a plurality of active regions that are arrayed, wherein each of the plurality of active regions comprises an active portion and an active extension portion;
a word line gate structure positioned in the substrate, wherein the word line gate structure runs through the plurality of active regions, and the word line gate structure comprises a word line layer and a word line isolation layer, and wherein the active extension portion covers a surface of the active portion and is at least partially positioned on the word line gate structure; and
a word line isolation extension portion positioned in the active extension portion, wherein the word line isolation extension portion is connected to the word line isolation layer and formed on a surface of the word line isolation layer.

2. The semiconductor structure according to claim 1, further comprising: an isolation region, wherein the isolation region is formed between the plurality of active regions.

3. The semiconductor structure according to claim 2, wherein the isolation region comprises an isolation portion and an isolation extension portion, wherein the isolation extension portion is connected to the isolation portion and positioned on a surface of the isolation portion, the isolation portion is positioned between active portions, the isolation extension portion is positioned between active extension portions, and the active extension portions are at least partially positioned on the surface of the isolation portion.

4. The semiconductor structure according to claim 1, further comprising: a capacitive contact portion, wherein the capacitive contact portion is formed on the active extension portion and is connected to the active extension portion.

5. The semiconductor structure according to claim 1, wherein a word line trench is formed in the substrate, the word line gate structure is formed in the word line trench, and the word line gate structure further comprises a gate oxide layer, wherein the gate oxide layer is formed on a side wall and a bottom wall of the word line trench.

6. The semiconductor structure according to claim 5, wherein the word line layer is formed on a side wall of the gate oxide layer, and the word line isolation layer is formed on a bottom wall of the gate oxide layer, the side wall of the gate oxide layer, and a side wall of the word line layer.

7. The semiconductor structure according to claim 5, wherein the active extension portion is positioned on a surface of the gate oxide layer and a portion of the surface of the word line isolation layer.

8. A method for preparing a semiconductor structure, comprising:
providing a substrate, the substrate having an active portion and a word line gate structure being formed in the substrate, wherein the word line gate structure comprises a word line layer and a word line isolation layer;
forming an active extension layer on a surface of the substrate;
removing a portion of the active extension layer to form an active extension portion, and forming a first opening exposing the word line isolation layer, wherein the active extension portion covers a surface of the active portion and is at least partially positioned on the word line gate structure, and the active extension portion and the active portion jointly constitute an active region; and
forming a word line isolation extension portion in the first opening.

9. The method for preparing the semiconductor structure according to claim 8, wherein an isolation portion is further formed in the substrate, and the isolation portion is formed between the active portions;
wherein removing the portion of the active extension layer to form the active extension portion comprises: forming a second opening exposing the isolation portion in the active extension layer, wherein the active extension portion is at least partially positioned on a surface of the isolation portion; and
wherein forming the word line isolation extension portion comprises: forming an isolation extension portion in the second opening, wherein the isolation extension portion and the isolation portion collaboratively form an isolation region.

10. The method for preparing the semiconductor structure according to claim 8, wherein removing the portion of the active extension layer to form the active extension portion comprises:
removing a portion of the active extension portion to form the first opening exposing the word line isolation layer; and
etching the substrate to form an isolation trench between adjacent active regions; and
wherein forming the word line isolation extension portion comprises: forming an isolation region in the isolation trench.

11. The method for preparing the semiconductor structure according to claim 8, further comprising: forming a capacitive contact portion, wherein the capacitive contact portion is formed on the active extension portion and is connected to the active extension portion.

12. The method for preparing the semiconductor structure according to claim 8, further comprising: forming a word line trench in the substrate, wherein the word line gate structure is formed in the word line trench, the word line gate structure further comprises a gate oxide layer, and the gate oxide layer is formed on a side wall and a bottom wall of the word line trench.

13. The method for preparing the semiconductor structure according to claim 12, wherein the word line layer is formed on a side wall of the gate oxide layer, and the word line isolation layer is formed on a bottom wall of the gate oxide layer, the side wall of the gate oxide layer, and a side wall of the word line layer.

14. The method for preparing the semiconductor structure according to claim 12, wherein the active extension portion is positioned on a surface of the gate oxide layer and a portion of the surface of the word line isolation layer.
